(19) United States
(12) Patent Application Publication
(10) Pub. No.: US 2021/0050296 A1
(43) Pub. Date: Feb. 18, 2021

(54) SEMICONDUCTOR PACKAGE STRUCTURE AND MANUFACTURING METHOD THEREOF

(71) Applicant: Powertech Technology Inc., Hsinchu County (TW)

(72) Inventors: Pei-Chun Tsai, Hsinchu County (TW); Hung-Hsin Hsu, Hsinchu County (TW); Shang-Yu Chang Chien, Hsinchu County (TW); Nan-Chun Lin, Hsinchu County (TW)

(73) Assignee: Powertech Technology Inc., Hsinchu County (TW)

(21) Appl. No.: 16/568,256

(22) Filed: Sep. 12, 2019

(30) Foreign Application Priority Data
Aug. 12, 2019 (TW) 108128494

(51) Int. Cl. H01L 23/538; H01L 25/065; H01L 23/00; H01L 23/31; H01L 23/58; H01L 21/48; H01L 25/00

(52) U.S. Cl. CPC H01L 23/5386; H01L 2224/92125; H01L 24/32; H01L 23/3128; H01L 23/585; H01L 21/4857; H01L 25/50; H01L 23/5385; H01L 24/16; H01L 24/73; H01L 24/81; H01L 24/83; H01L 24/92; H01L 21/4853; H01L 2224/16227; H01L 2224/13025; H01L 24/13; H01L 2224/32225; H01L 2224/73204; H01L 25/0655

(57) ABSTRACT

A semiconductor package structure including a circuit substrate, a redistribution layer, and at least two dies is provided. The circuit substrate has a first surface and a second surface opposite the first surface. The redistribution layer is located on the first surface. The redistribution layer is electrically connected to the circuit substrate. The spacing of the opposing sidewalls of the redistribution layer is less than the spacing of the opposing sidewalls of the circuit substrate. The redistribution layer is directly in contact with the circuit substrate. At least two dies are disposed on the redistribution layer. Each of the at least two dies has an active surface facing the circuit substrate. One of the at least two dies is electrically connected to the other of the at least two dies by the redistribution layer. A manufacturing method of a semiconductor package structure is also provided.

### CROSS-REFERENCE TO RELATED APPLICATION

This application claims the priority benefit of Taiwan application serial no. 108128494, filed on Aug. 12, 2019. The entirety of the above-mentioned patent application is hereby incorporated by reference herein and made a part of this specification.

### BACKGROUND

### Technical Field

The present invention is related to a package structure and a manufacturing method thereof, and more particularly to a semiconductor package structure and a manufacturing method thereof.

### Description of Related Art

For electronic products to achieve a compact design, the semiconductor packaging technology is also progressing to develop products that meet the requirements of small size, light weight, high density, and having high competitiveness in the market. In terms of a multi-function semiconductor package, how to enhance the electrical capability and/or performance of the semiconductor package structure while miniaturizing the semiconductor package structure is a big challenge for persons skilled in the art.

### SUMMARY

The present invention provides a semiconductor package structure and a manufacturing method thereof for enhancing the electrical capability and/or performance of the semiconductor package structure while miniaturizing the semiconductor package structure.

The present invention provides a semiconductor package structure including a circuit substrate, a redistribution layer, and at least two dies. The circuit substrate has a first surface and a second surface opposite the first surface. The redistribution layer is located on the first surface. The redistribution layer is electrically connected to the circuit substrate. The spacing of the opposing sidewalls of the redistribution layer is less than the spacing of the opposing sidewalls of the circuit substrate. The redistribution layer is directly in contact with the circuit substrate. At least two dies are disposed on the redistribution layer. Each of the at least two dies has an active surface facing the circuit substrate. One of the at least two dies is electrically connected to the other of the at least two dies by the redistribution layer.

The present invention provides a manufacturing method of a semiconductor package structure including at least the following steps. A circuit substrate is provided. The circuit substrate has a first surface and a second surface opposite the first surface. A redistribution layer is formed on the first surface. The redistribution layer is electrically connected to the circuit substrate. The spacing of the opposing sidewalls of the redistribution layer is less than the spacing of the opposing sidewalls of the circuit substrate. The redistribution layer is directly in contact with the circuit substrate. At least two dies are disposed on the redistribution layer. Each of the at least two dies has an active surface facing the circuit substrate. One of the at least two dies is electrically connected to the other of the at least two dies by the redistribution layer.

Based on the above, the semiconductor package structure of the present invention can lower the winding density of the circuit substrate and reduce the thickness of the circuit substrate since one of the at least two dies is electrically connected to the other of the at least two dies by the redistribution layer, so as to miniaturize the semiconductor package structure and lower the production cost. Furthermore, since the redistribution layer has a better line-and-space (L/S) than the circuit substrate, by electrically connecting one of the at least two dies to the other of the at least two dies by the redistribution layer, the spacing between two adjacent dies can be shortened, so as to enhance the electrical capability and/or performance of the semiconductor package structure.

To make the aforementioned and other features of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1D are partial cross-sectional views showing a partial manufacturing method of a semiconductor package structure according to an embodiment of the present invention.

FIG. 2 is a partial cross-sectional view showing a semiconductor package structure according to another embodiment of the present invention.

FIG. 3 is a partial cross-sectional view showing a semiconductor package structure according to also another embodiment of the present invention.

FIG. 4 is a partial cross-sectional view showing a semiconductor package structure according to yet another embodiment of the present invention.

FIG. 5 is a partial cross-sectional view showing a semiconductor package structure according to still another embodiment of the present invention.

### DETAILED DESCRIPTION OF DISCLOSED EMBODIMENTS

The directional terms used herein (for example, up, down, right, left, front, back, top, and bottom) are only for referencing to the drawings and are not intended to imply absolute directions.

Unless otherwise specifically stated, the steps of any method described herein are not intended to be construed as requiring execution in a particular order.

The present invention will be more comprehensively expounded with reference to the drawings of the embodiments. However, the present invention may also be embodied in a variety of different forms and should not be limited to the embodiments described herein. The thickness, dimensions, or size of layers or regions in the drawings are enlarged for clarity. The same or similar reference numerals denote the same or similar elements, which will not be reiterated one by one in the following paragraphs.

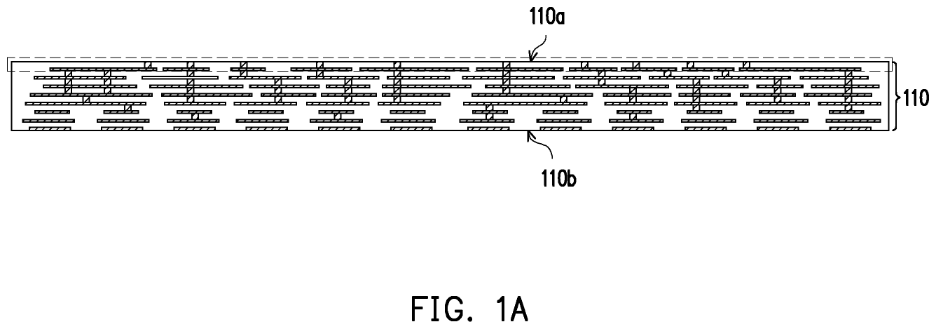

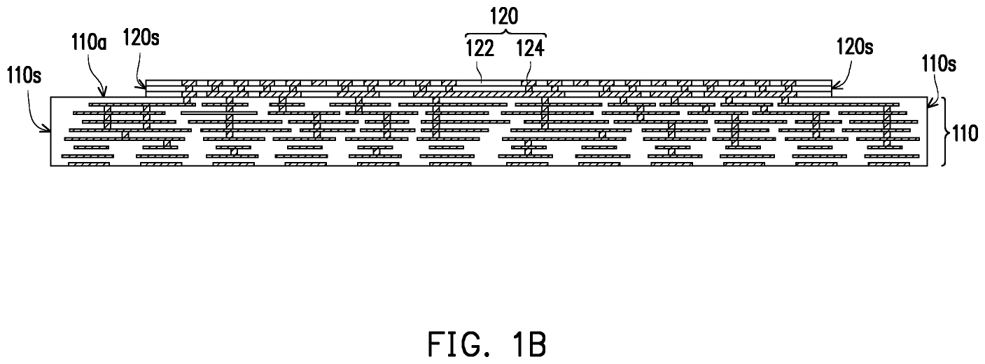

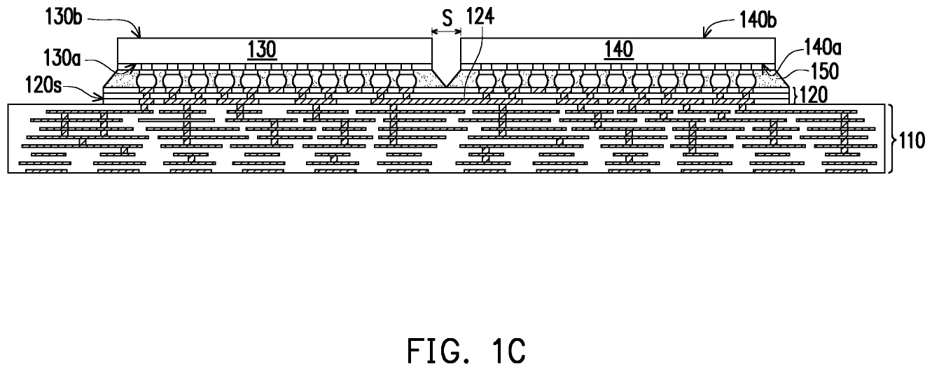

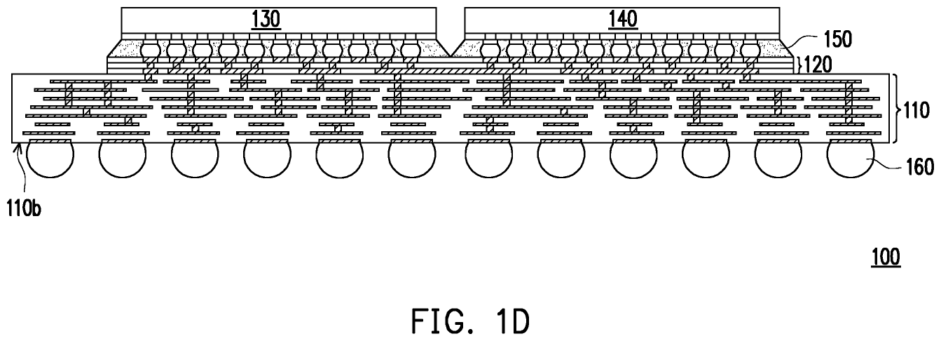

FIG. 1A to FIG. 1D are partial cross-sectional views showing a partial manufacturing method of a semiconductor package structure 100 according to an embodiment of the present invention.

Referring to FIG. 1A, in the embodiment, the manufacturing process of the semiconductor package structure 100 may include the following steps. First, a circuit substrate 110 is provided. The circuit substrate 110 has a first surface 110a and a second surface 110b opposite the first surface 110a. In some embodiments, the circuit substrate 110 may be a printed circuit board (PCB), an organic substrate, or a high-density interconnect substrate. Here, the present invention does not limit the type of the circuit substrate 110. As long as the circuit substrate 110 has an appropriate routing circuit inside to provide the electrical connection required in the subsequent process, the circuit substrate 110 falls within the protected scope of the present invention.

Referring to FIG. 1B, a redistribution layer 120 is formed on the first surface 110a of the circuit substrate 110, wherein the redistribution layer 120 is electrically connected to the circuit substrate 110. In the embodiment, the spacing of the opposing sidewalls 120s of the redistribution layer 120 is less than the spacing of the opposing sidewalls 110s of the circuit substrate 110. For example, the sidewalls 120s of the redistribution layer 120 may be indented from the sidewalls 110s of the circuit substrate 110 to expose a portion of the first surface 110a of the circuit substrate 110. The redistribution layer 120 does not completely cover the first surface 110a of the circuit substrate 110 and the redistribution layer 120 may be the first surface 110a partially covering the circuit substrate 110. Here, the present invention does not limit the size of the area of the redistribution layer 120 partially covering the circuit substrate 110, which may be determined in view of the number of dies subsequently disposed above.

In the embodiment, the redistribution layer 120 and the circuit substrate 110 may be directly in contact. For example, the redistribution layer 120 is not part of the circuit substrate 110. The redistribution layer 120 may be formed on the first surface 110a of the circuit substrate 110 directly by processes such as deposition, photolithography, and etching.

The redistribution layer 120 may include a plurality of dielectric layers 122 and a plurality of patterned conductive layers 124 alternately stacked. In an embodiment, for example, a conductive material such as copper, aluminum, or nickel may be formed on the dielectric layer 122 by sputtering, evaporation, or electroplating processes. Then, the conductive material is patterned by photolithography and etching processes to form the patterned conductive layer 124. In some other embodiments, the patterned conductive layer 124 may be formed before the dielectric layer 122. The order in which the dielectric layer 122 and the patterned conductive layer 124 are formed may be adjusted in view of design requirements. The material of the dielectric layer 122 may include an inorganic material or an organic material. The inorganic material may be, for example, silicon oxide, silicon nitride, silicon carbide, silicon oxynitride, or similar inorganic dielectric materials. The organic material may be, for example, polyimide (PI), butylcyclobutene (BCB), or similar organic dielectric materials. The present invention is not limited thereto.

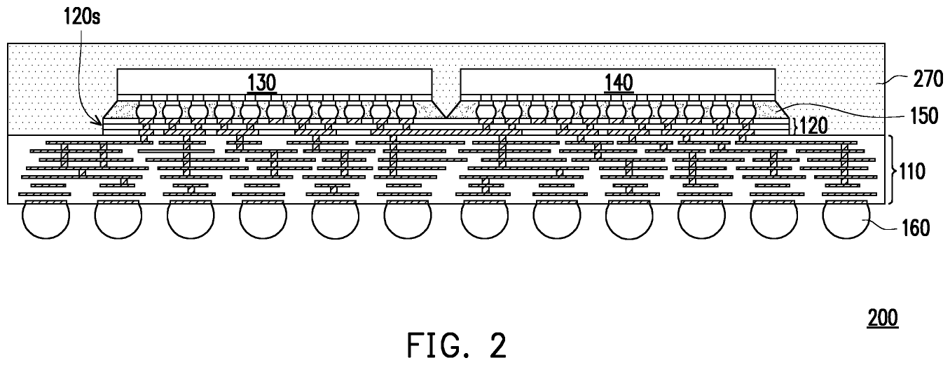

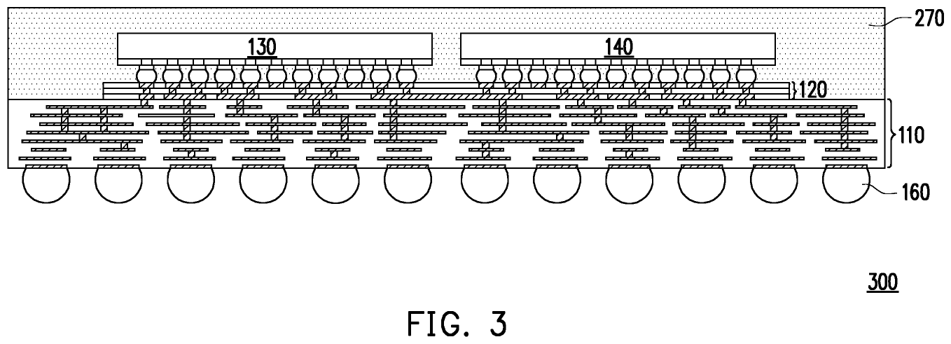

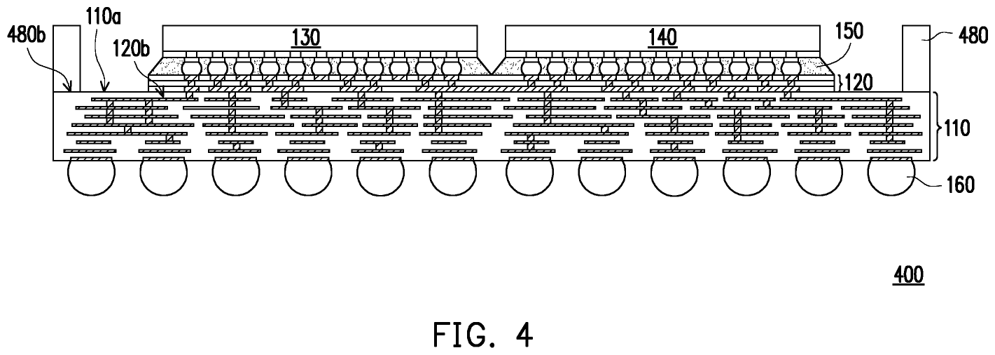

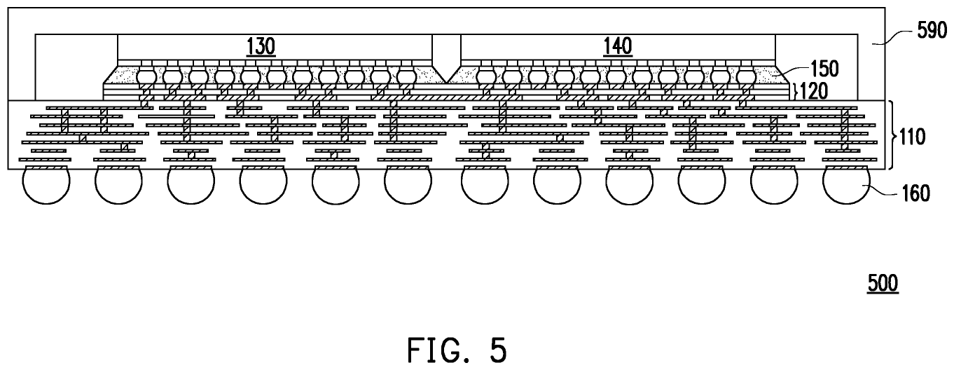

Referring to FIG. 1C, after the redistribution layer 120 is formed, at least two dies are disposed on the redistribution layer 120. In some embodiments, as shown by the exemplary embodiments depicted in FIG. 1C, FIG. 1D, FIG. 2, FIG. 3, FIG. 4, and FIG. 5, at least two dies may include a first die 130 and a second die 140. However, the present invention is not limited thereto and the number of the at least two dies may be three or more. In some embodiments, the dies in the at least two dies may have different functions. However, the present invention is not limited thereto and some or all of the dies in the at least two dies may have the same function.

In the embodiment, each of the at least two dies has an active surface facing the circuit substrate 110 and a back surface opposite the active surface. For example, the first die 130 has an active surface 130a and a back surface 130b opposite the active surface 130a, while the second die 140 has an active surface 140a and a back surface 140b opposite the active surface 140a, and the first die 130 and the second die 140 are disposed on the surface of the redistribution layer 120 away from the circuit substrate 110 in, for example, a flip-chip manner.

One of the at least two dies is electrically connected to the other of the at least two dies by the redistribution layer 120. For example, the first die 130 may be electrically connected to the second die 140 by the redistribution layer 120. In an embodiment, there is a portion of the patterned conductive layer 124 between the adjacent first die 130 and second die 140 used for the electrical connection between the first die 130 and the second die 140. In an embodiment, the portion of the patterned conductive layer 124 may extend from below the first die 130 to below the second die 140. In an embodiment, there is a spacing S between the adjacent first die 130 and second die 140, and the orthographic projection of the spacing S on the circuit substrate 110 may partially overlap with the orthographic projection of the patterned conductive layer 124 on the circuit substrate 110.

Since one of the at least two dies is electrically connected to the other of the at least two dies by the redistribution layer 120 to interconnect between the at least two dies, the winding density of the circuit substrate 110 can be lowered and the thickness of the circuit substrate 110 can be reduced, so as to miniaturize the semiconductor package structure 100 and reduce the production cost. In addition, the redistribution layer 120 may have a better line-and-space (L/S) than the circuit substrate 110. For example, the L/S of the redistribution layer 120 may be less than 5 μm/5 μm. Therefore, by electrically connecting one of the at least two dies to the other of the at least two dies by the redistribution layer 120, the spacing between the adjacent two dies (such as the spacing S between the first die 130 and the second die 140) can be shortened, so as to improve the electrical capability and/or performance of the semiconductor package structure 100. In an embodiment, since one of the at least two dies is electrically connected to the other of the at least two dies by the redistribution layer 120, the step of completely replacing the process or material of the top layer circuit (the dashed box region in FIG. 1A) of the circuit substrate 110 for connecting the at least two dies may be omitted.

Continue referring to FIG. 1C, in some embodiments, after the at least two dies are disposed, an underfill 150 may be formed between the at least two dies and the redistribution layer 120. However, the present invention is not limited thereto, and in other embodiments, the underfill 150 may not be formed between the at least two dies and the redistribution layer 120. The underfill 150 may extend between the opposing sidewalls 120s of the redistribution layer 120. The underfill 150 may be formed by capillary underfill filling (CUF) and the underfill 150 may include a polymer material, a resin, or a silica additive.

Referring to FIG. 1D, after the at least two dies are disposed, a plurality of conductive terminals 160 are formed on the second surface 110b, and the plurality of conductive terminals 160 are electrically connected to the circuit substrate 110. In an embodiment, the redistribution layer 120 and the circuit substrate 110 are located between the at least two dies and the plurality of conductive terminals 160. Therefore, the at least two dies may be electrically connected to the conductive terminals 160 by the redistribution layer 120 and the circuit substrate 110, so as to further increase the number of I/O connections in the semiconductor package structure 100.

It should be noted that the circuit layouts in the drawings are for illustrative purposes only. Therefore, in the drawings, the partially unconnected circuit in the circuit substrate 110 and the redistribution layer 120 may actually be electrically connected through conductive vias or conductive members in other directions in view of circuit design requirements.

After the above process, the manufacture of the semiconductor package structure 100 according to the embodiment may be substantially completed. The semiconductor package structure 100 includes the circuit substrate 110, the redistribution layer 120, and the at least two dies (the first die 130 and the second die 140). The circuit substrate has the first surface 110a and the second surface 110b opposite the first surface 110a. The redistribution layer 120 is located on the first surface 110a. The redistribution layer 120 is electrically connected to the circuit substrate 110. The spacing of the opposing sidewalls 120s of the redistribution layer 120 is less than the spacing of the opposing sidewalls 110s of the circuit substrate 110. The redistribution layer 120 is directly in contact with the circuit substrate 110. Each of the at least two dies has the active surface facing the circuit substrate 110. One of the at least two dies is electrically connected to the other of the at least two dies by the redistribution layer 120.

In the semiconductor package structure 100, since one of the at least two dies is electrically connected to the other of the at least two dies by the redistribution layer 120, the electrical capability and/or performance of the semiconductor package structure 100 can be improved while miniaturizing the semiconductor package structure 100.

It should be noted here that the following embodiments continue to use the reference numerals and some content of the above embodiment, wherein the same or similar reference numerals are used to denote the same or similar elements, and descriptions of the same technical content are omitted. Please refer to the foregoing embodiments for the descriptions of the omitted parts, which will not be reiterated in the following embodiments.

FIG. 2 is a partial cross-sectional view showing a semiconductor package structure 200 according to another embodiment of the present invention. Referring to FIG. 2, the semiconductor package structure 200 of the present embodiment is similar to the semiconductor package structure 100 of the above embodiment, except that the semiconductor package structure 200 of the present embodiment further includes an encapsulant 270. The encapsulant 270 may encapsulate at least two dies (a first die 130 and a second die 140) and a redistribution layer 120, and the encapsulant 270 covers opposing sidewalls 120s of the redistribution layer 120. Therefore, the encapsulant 270 can protect electronic elements in the semiconductor package structure 200 and lower the warpage problem of the semiconductor package structure 200.

FIG. 3 is a partial cross-sectional view showing a semiconductor package structure 300 according to also another embodiment of the present invention. Referring to FIG. 3, the semiconductor package structure 300 of the present embodiment is similar to the semiconductor package structure 200 of the above embodiment, except that the semiconductor package structure 300 of the present embodiment does not form the underfill 150 between the at least two dies (the first die 130 and the second die 140) and the redistribution layer 120.

FIG. 4 is a partial cross-sectional view showing a semiconductor package structure 400 according to yet another embodiment of the present invention. The semiconductor package structure 400 of the present embodiment is similar to the semiconductor package structure 100 of the above embodiment, except that the semiconductor package structure 400 of the present embodiment further includes a metal ring 480. The metal ring 480 may be located on a first surface 110 and surround at least two dies (a first die 130 and a second die 140). Therefore, the metal ring 480 can protect electronic elements in the semiconductor package structure 400 and reduce the warpage problem of the semiconductor package structure 400. In an embodiment, a bottom surface 480b of the metal ring 480 and a bottom surface 120b of the redistribution layer 120 may be basically coplanar, but the present invention is not limited thereto.

FIG. 5 is a partial cross-sectional view showing a semiconductor package structure 500 according to still another embodiment of the present invention. The semiconductor package structure 500 of the present embodiment is similar to the semiconductor package structure 100 of the above embodiment, except that the semiconductor package structure 500 of the present embodiment further includes a lid 590. The lid 590 at least covers a back surface of at least two dies (a first die 130 and a second die 140) opposite an active surface. Therefore, the lid 590 can protect electronic elements in the semiconductor package structure 500 and reduce the warpage problem of the semiconductor package structure 500. In an embodiment, the lid 590 encloses at least two dies and the redistribution layer 120, but the present invention is not limited thereto. In an embodiment, the lid 590 may form a plurality of cavities with the at least two dies (the first die 130 and the second die 140) and the redistribution layer 120.

Based on the above, the semiconductor package structure of the present invention can lower the winding density of the circuit substrate and reduce the thickness of the circuit substrate since one of the at least two dies is electrically connected to the other of the at least two dies by the redistribution layer, so as to miniaturize the semiconductor package structure and lower the production cost. Furthermore, since the redistribution layer has a better L/S than the circuit substrate, by electrically connecting one of the at least two dies to the other of the at least two dies by the redistribution layer, the spacing between the two adjacent dies can be shortened, so as to enhance the electrical capability and/or performance of the semiconductor package structure. In addition, the semiconductor package structure of the present invention may further include an encapsulant, a metal ring, or a lid, so as to further protect the electronic elements in the semiconductor package structure and reduce the warpage problem of the semiconductor package structure.

Although the disclosure has been disclosed in the above embodiments, the embodiments are not intended to limit the disclosure. It will be apparent to persons skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor package structure, comprising:
a circuit substrate having a first surface and a second surface opposite the first surface;
a redistribution layer, located on the first surface, wherein:
the redistribution layer is electrically connected to the circuit substrate;
a spacing of opposing sidewalls of the redistribution layer is less than a spacing of opposing sidewalls of the circuit substrate; and
the redistribution layer is directly in contact with the circuit substrate; and
at least two dies, disposed on the redistribution layer, wherein:
each of the at least two dies has an active surface facing the circuit substrate; and
one of the at least two dies is electrically connected to another of the at least two dies by the redistribution layer.

2. The semiconductor package structure according to claim 1, wherein the redistribution layer exposes a portion of the first surface of the circuit substrate.

3. The semiconductor package structure according to claim 1, wherein the redistribution layer comprises a plurality of dielectric layers and a plurality of patterned conductive layers alternately stacked.

4. The semiconductor package structure according to claim 3, wherein a portion of the patterned conductive layer is between adjacent two of the at least two dies.

5. The semiconductor package structure according to claim 3, wherein a spacing is between adjacent two of the at least two dies and an orthographic projection of the spacing on the circuit substrate overlaps with an orthographic projection of the patterned conductive layer on the circuit substrate.

6. The semiconductor package structure according to claim 1, wherein the redistribution layer is not part of the circuit substrate.

7. The semiconductor package structure according to claim 1, further comprising an underfill filled between the at least two dies and the redistribution layer.

8. The semiconductor package structure according to claim 7, wherein the underfill extends between the opposing sidewalls of the redistribution layer.

9. The semiconductor package structure according to claim 1, further comprising an encapsulant encapsulating the at least two dies and the redistribution layer.

10. The semiconductor package structure according to claim 9, wherein the encapsulant covers the opposing sidewalls of the redistribution layer.

11. The semiconductor package structure according to claim 1, further comprising a metal ring on the first surface and surrounding the at least two dies.

12. The semiconductor package structure according to claim 11, wherein a bottom surface of the metal ring and a bottom surface of the redistribution layer are basically coplanar.

13. The semiconductor package structure according to claim 1, further comprising a lid at least covering at least a back surface of the at least two dies opposite the active surface.

14. The semiconductor package structure according to claim 13, wherein the lid encloses the at least two dies and the redistribution layer.

15. The semiconductor package structure according to claim 13, wherein a plurality of cavities are formed between the lid and the at least two dies and the redistribution layer.

16. The semiconductor package structure according to claim 1, further comprising a plurality of conductive terminals located on the second surface and the plurality of conductive terminals are electrically connected to the circuit substrate.

17. A manufacturing method of a semiconductor package structure, comprising:
providing a circuit substrate, wherein the circuit substrate has a first surface and a second surface opposite the first surface;
forming a redistribution layer on the first surface, wherein:
the redistribution layer is electrically connected to the circuit substrate;
a spacing of opposing sidewalls of the redistribution layer is less than a spacing of opposing sidewalls of the circuit substrate; and
the redistribution layer is directly in contact with the circuit substrate; and
disposing at least two dies on the redistribution layer, wherein:
each of the at least two dies has an active surface facing the circuit substrate; and
one of the at least two dies is electrically connected to another of the at least two dies by the redistribution layer.

18. The manufacturing method of a semiconductor package structure according to claim 17, wherein the step of forming the redistribution layer comprises forming a plurality of dielectric layers and a plurality of patterned conductive layers alternately stacked on the first surface.

19. The manufacturing method of a semiconductor package structure according to claim 18, wherein a portion of the patterned conductive layer extends from below one of the at least two dies to below another of the at least two dies.

20. The manufacturing method of a semiconductor package structure according to claim 17, further comprising forming a plurality of conductive terminals on the second surface, wherein the at least two dies are electrically connected to the plurality of conductive terminals by the redistribution layer and the circuit substrate.
